(19) United States
(12) Patent Application Publication
(10) Pub. No.: US 2019/0271073 A1
(43) Pub. Date: Sep. 5, 2019

(54) SiC MEMBER AND SUBSTRATE-HOLDING MEMBER FORMED OF SiC MEMBER, AND METHOD FOR PRODUCING THE SAME

(71) Applicant: NGK SPARK PLUG CO., LTD., Nagoya (JP)

(72) Inventors: Norio ONODERA, Sendai-city (JP); Keisuke SATO, Sendai-city (JP); Ryota SATO, Sendai-city (JP)

(21) Appl. No.: 16/291,113

(22) Filed: Mar. 4, 2019

(30) Foreign Application Priority Data
Mar. 5, 2018 (JP) 2018-038616

(51) Int. Cl. C23C 16/32; C23C 16/56

(52) U.S. Cl. CPC C23C 16/325; B24B 37/30; C23C 16/56

(57) ABSTRACT

A method for producing a SiC member includes a chemical vapor deposition (CVD) step of forming a SiC member formed of β-SiC by a CVD method and a heat treatment step of heat-treating the SiC member in an inert atmosphere at a temperature of higher than 2000° C. and 2200° C. or lower to partly transform β-SiC into α-SiC.

### CROSS REFERENCE TO RELATED APPLICATION

The present application claims priority to Japanese Patent Application No. 2018-038616, which was filed on Mar. 5, 2018, the disclosure of which is herein incorporated by reference in its entirety.

### BACKGROUND OF THE INVENTION

### 1. Field of the Invention

The present invention relates to a SiC member and a substrate-holding member formed of the SiC member and to a method for producing the SiC member and the substrate-holding member.

### 2. Description of the Related Art

SiC members formed of a SiC sintered body have high rigidity and high wear resistance. Therefore, substrate-holding members, such as vacuum chucks, for holding a substrate such as a wafer during various treatments of a semiconductor production process are formed of a SiC member in the related art (e.g., refer to PTL 1).

PTL 2 discloses that after a polycrystalline β-SiC layer is formed on a surface of a substrate formed of an α-SiC sintered body by a chemical vapor deposition (CVD) method, heat treatment is performed at 1850° C. to 2000° C. to transform β-SiC into α-SiC. As a result of the heat treatment, the transformation of β-SiC into α-SiC proceeds from the boundary surface between α-SiC and β-SiC. Almost all the β-SiC is transformed into α-SiC, and thus a SiC member having a uniform crystalline structure is obtained.

PTL 3 discloses that a high-purity CVD-SiC member for semiconductor heat treatment, the member being formed of a β-SiC columnar crystal that has grown in a direction vertical to a substrate and an α-SiC fine crystal that has grown in a direction parallel to the substrate, is obtained by appropriately controlling the method for supplying raw material gases and the temperature.

### CITATION LIST

### Patent Literature

PTL 1: Patent Document 1 is Japanese Unexamined Patent Application Publication No. 2001-302397.

PTL 2: Patent Document 2 is Japanese Patent No. 3154053.

PTL 3: Patent Document 3 is Japanese Patent No. 3524679.

### BRIEF SUMMARY OF THE INVENTION

In the structure described in PTL 2, however, almost all the β-SiC is transformed into α-SiC. Therefore, β-SiC that is denser and has higher strength and wear resistance than α-SiC is substantially not present, resulting in insufficient strength and wear resistance.

In the structure described in PTL 3, for example, when grinding or polishing is performed to form pins on the surface, the residual stress is generated between crystals because of anisotropy between the β-SiC columnar crystal and the α-SiC fine crystal, which makes it difficult to perform processing with high dimensional accuracy. Furthermore, the dimensional accuracy may deteriorate after long-term use because of the influence of orientation or the like.

Accordingly, it is an object of the present invention to provide a SiC member having high strength and high wear resistance and a method for producing the SiC member. It is another object of the present invention to provide a substrate-holding member whose processing accuracy can be improved and can be maintained for a long time, and a method for producing the substrate-holding member.

A method for producing a SiC member according to an aspect of the present invention includes a step of forming a SiC member formed of β-SiC by a chemical vapor deposition (CVD) method and a step of heat-treating the SiC member in an inert atmosphere at a temperature of higher than 2000° C. and 2200° C. or lower to partly cause phase transition of the β-SiC into α-SiC.

In the method for producing a SiC member according to an aspect of the present invention, only a part of β-SiC is subjected to phase transition into α-SiC in the SiC member, and therefore good characteristics of β-SiC, such as high denseness, high strength, and high wear resistance, are left.

A method for producing a substrate-holding member according to an aspect of the present invention is a method for producing a substrate-holding member for holding a substrate using the above SiC member according to an aspect of the present invention. The method includes a step of forming a main surface positioned lower than a top surface of the SiC member by partly removing the top surface and forming a plurality of protruding portions that protrude from the main surface and a step of planarizing tip surfaces of the plurality of protruding portions so that the tip surfaces protrude from the main surface with the same height so as to be flush with each other.

In the method for producing a substrate-holding member according to an aspect of the present invention, β-SiC constituting the SiC member is partly subjected to phase transition into α-SiC and thus the crystal orientation is reduced compared with the case where a SiC member formed of only β-SiC is processed. Therefore, processing can be performed with high dimensional accuracy due to low anisotropy. Furthermore, since the residual stress generated when the SiC member is processed is relaxed, the deterioration of dimensional accuracy due to long-term use can be suppressed.

A SiC member according to an aspect of the present invention is a SiC member containing α-SiC and α-SiC, wherein a ratio of an intensity of a maximum peak derived from the α-SiC at a diffraction angle 2θ of 34°±0.5° to an intensity of a maximum peak among diffraction peaks derived from the β-SiC in an X-ray diffraction spectrum is 3% or more and 30% or less.

In the SiC member according to an aspect of the present invention, the following is found from Examples described later. Since the intensity ratio of the maximum peaks is 3% or more, the proportion of α-SiC is large enough to effectively relax the internal stress. Since the intensity ratio of the maximum peaks is 30% or less, the proportion of α-SiC is small enough to achieve high strength and high wear resistance.

A substrate-holding member according to an aspect of the present invention is a substrate-holding member formed of the above SiC member according to an aspect of the present invention. For example, the SiC member includes a substrate having a main surface and a plurality of protruding portions which protrude from the main surface of the substrate with the same height and whose tip surfaces are flush with each other.

This can provide a substrate-holding member capable of holding a substrate with good flatness for a long time.

### BRIEF DESCRIPTION OF THE DRAWINGS

Illustrative aspects of the invention will be described in detail with reference to the following figures wherein:

FIG. 1 is a flow chart illustrating a method for producing a SiC member and a substrate-holding member according to an embodiment of the present invention;

FIG. 2 is a schematic sectional view illustrating a SiC member according to an embodiment of the present invention;

FIG. 3 is a schematic sectional view illustrating a substrate-holding member according to an embodiment of the present invention;

FIG. 4 is a graph illustrating the result of X-ray diffraction measurement of a CVD-SiC member in Example 1;

FIG. 5 is a graph illustrating the result of X-ray diffraction measurement of a SiC member in Example 1; and

FIG. 6 is a graph illustrating the result of X-ray diffraction measurement of a SiC member in Comparative Example 3.

### DETAILED DESCRIPTION OF EXEMPLARY EMBODIMENTS OF THE INVENTION

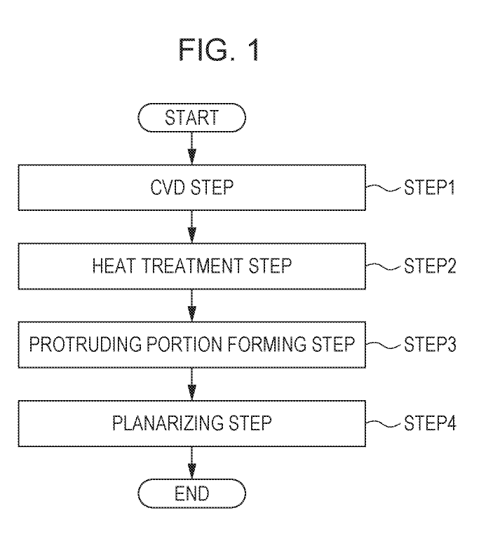

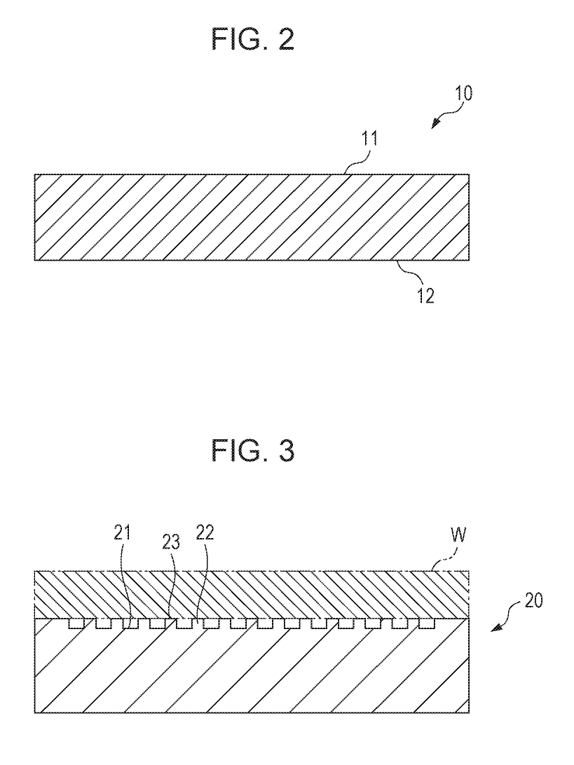

A method for producing a SiC member 10 according to an embodiment of the present invention will be described with reference to FIG. 1 and FIG. 2. In FIG. 2 and FIG. 3 described later, each component is deformed to clarify the structures of the SiC member 10 and a substrate-holding member 20 described later, and thus the dimensions are different from actual dimensions.

The method for producing a SiC member 10 includes a chemical vapor deposition (CVD) step (STEP 1) of forming a SiC member (hereafter also referred to as a CVD-SiC member) formed of β-SiC by a CVD method and a heat treatment step (STEP 2) of heat-treating the CVD-SiC member in an inert atmosphere at a temperature of higher than 2000° C. and 2200° C. or lower to form a SiC member whose β-SiC is partly subjected to phase transition into α-SiC.

In the CVD step (STEP 1), a CVD-SiC member formed of β-SiC is formed by a CVD method. The CVD method may be any publicly known CVD method such as a thermal CVD method, a plasma CVD method, a super-growth method, or an alcohol CVD method. SiC formed by a CVD method is β-SiC having a 3C cubic crystal structure.

The CVD-SiC member may be, for example, a member obtained by forming a SiC film through growth of SiC on a substrate formed of a high-purity isotropic graphite by a thermal CVD method and then removing the substrate. The raw material gas in the thermal CVD method may be, for example, a mixture gas of trichloromethylsilane (CH₃SiCl₃) and hydrogen gas. The raw material gas may also be, for example, a mixture gas of silicon tetrachloride (SiCl₄) and hydrogen gas.

The CVD-SiC member is a β-SiC bulk body that is denser and has higher strength and wear resistance than an α-SiC bulk body. However, β-SiC has orientation, which makes it difficult to achieve highly accurate flatness required for substrate-holding members such as vacuum chucks. Even if highly accurate flatness is achieved at the initial stage, the flatness deteriorates after long-term use.

Thus, α-SiC is partly mixed in β-SiC through the heat treatment in the heat treatment step (STEP 2). As a result, the α-SiC mixed in β-SiC reduces the orientation of β-SiC, which can solve the above problem.

The heat treatment is performed in an inert atmosphere such as a N₂, Ar, or vacuum atmosphere to prevent the oxidation of SiC.

The heat treatment temperature is higher than 2000° C. and 2200° C. or lower and preferably higher than 2000° C. and 2100° C. or lower. If the heat treatment temperature is 2000° C. or lower, the phase transition from β-SiC into α-SiC substantially does not proceed or the phase transition takes a very long time, which unfavorably requires a long heat treatment time. If the heat treatment temperature is higher than 2200° C., the phase transition from β-SiC into α-SiC rapidly proceeds, which unfavorably makes it difficult to control the formation of α-SiC.

The heat treatment time is preferably 0.5 hours or more and 10 hours or less and more preferably 0.5 hours or more and 2 hours or less. This is because the following is found from Examples described later. That is, if β-SiC is heat-treated in an inert atmosphere at a temperature of higher than 2000° C. and 2200° C. or lower, the phase transition of part of the crystal structure of β-SiC present near the surface into hexagonal 2H, 4H, and 6H-SiC structures proceeds to the inside with increasing the heat treatment time, and a SiC member 10 in which α-SiC is partly introduced into a β-SiC structure can be obtained.

When the β-SiC bulk body is heat-treated under the above conditions, the phase transition of β-SiC into α-SiC gradually and partly proceeds from the surface toward the inside. As a result, α-SiC is mixed in part of β-SiC to form composite SiC, which can relax the residual stress generated when the SiC member 10 is processed compared with SiC members formed of only β-SiC. Since most of the SiC member 10 is formed of β-SiC, the SiC member 10 substantially has the characteristics of β-SiC, such as high denseness, high strength, and high wear resistance.

In the method disclosed in PTL 2, the heat treatment is performed at a temperature of 1850° C. to 2000° C., and thus the phase transition of β-SiC into α-SiC proceeds from the boundary surface between α-SiC and β-SiC. In contrast, in the present invention, the phase transition of β-SiC into α-SiC proceeds from the surface of the β-SiC bulk body toward the inside.

The difference in the direction in which the phase transition proceeds is believed to be because of the difference in heat treatment temperature range. Although this is still unclear, it is believed that the phase transition from the surface proceeds from ends at which chemical bonds are broken and sites modified with impurities such as oxygen at ends, which requires higher energy (high temperature). As described above, it is found that when the heat treatment is performed at a temperature of higher than 2000° C. and 2200° C. or lower, the phase transition of β-SiC into α-SiC proceeds from the surface of the β-SiC bulk body toward the inside. This is one of the reasons for which the present invention has been made.

The α-SiC generated as a result of phase transition through heat treatment is mainly formed of a 6H hexagonal crystal system, and the expansion coefficient is different in accordance with the crystal orientation. Herein, it is believed that the α-SiC generated as a result of phase transition also contains, for example, trace amounts of 2H and 4H hexagonal crystal systems. Therefore, the expansion coefficient of α-SiC mixed in β-SiC is different in accordance with the direction. Consequently, the α-SiC partly present around β-SiC having good crystallinity and strong orientation in a mixed manner relaxes the internal stress between β-SiC crystals, which allows processing with high accuracy when the SiC member 10 is ground and polished and achieves high flatness. Furthermore, even when the SiC member 10 is used for a long time, the deterioration of dimensional accuracy can be suppressed.

The reason for the relaxation of internal stress is assumed to be as follows. The internal stress of β-SiC is considered to be tensile stress and the strain is relaxed by the orientation of α-SiC having a large expansion coefficient. However, this is still unclear.

The proportion of α-SiC mixed in β-SiC is preferably in the predetermined range. For example, for the surface of the SiC member 10, the ratio of the intensity of the maximum peak derived from α-SiC at a diffraction angle 2θ of 34°±0.5° to the intensity of the maximum peak among diffraction peaks derived from β-SiC in an X-ray diffraction spectrum is preferably 3% or more and 30% or less. The reason for this is as follows. If the intensity ratio of the maximum peaks is less than 3%, the proportion of α-SiC is excessively small and thus an effect of relaxing the internal stress is insufficient. If the intensity ratio of the maximum peaks is more than 30%, the proportion of α-SiC is excessively large and thus the strength and the wear resistance decrease.

Next, a method for producing a substrate-holding member 20 according to an embodiment of the present invention will be described with reference to FIG. 1 to FIG. 3.

This production method is a method for producing a substrate-holding member 20 for holding a substrate W such as a semiconductor wafer after the external shape of the SiC member 10 is optionally processed by grinding or the like. The substrate-holding member 20 holds the substrate W through tip surfaces 23 of a plurality of protruding portions 22 that protrude from the main surface 21 closer to the top surface 11 of the SiC member 10 with the same height.

This production method includes a protruding portion forming step (STEP 3) of forming a main surface 21 positioned lower than a top surface 11 of the SiC member 10 by partly removing the top surface 11 and forming a plurality of protruding portions 22 that protrude from the main surface 21 and a planarizing step (STEP 4) of planarizing the tip surfaces 23 of the plurality of protruding portions 22 so that the tip surfaces 23 protrude from the main surface 21 with the same height so as to be flush with each other.

In the protruding portion forming step (STEP 3), first, the main surface 21 is formed by partly removing the top surface 11 of the SiC member 10 using sandblasting or a machining center so as to be positioned lower than the top surface 11 (at a position close to the bottom surface 12 opposite to the top surface 11). The plurality of protruding portions 22 that protrude from the main surface 21 are formed. By partly removing the top surface 11, portions left without being removed serve as the protruding portions 22. The protruding portions 22 may have any shape such as a column, a prism, a truncated cone, or a truncated pyramid, and may also have steps.

In the planarizing step (STEP 4), polishing is preferably performed using a lapping machine, a polishing machine, or the like so that the tip surfaces 23 of the plurality of protruding portions 22 protrude from the main surface 21 with the same height so as to be flush with each other.

As described above, α-SiC is partly present around β-SiC in a mixed manner in a portion subjected to grinding or polishing near the top surface 11 of the SiC member 10, and the crystal orientation is reduced. Thus, processing can be performed with high dimensional accuracy due to low anisotropy. For example, the following very good planeness can be achieved: the surface roughness Ra of the tip surfaces 23 of the plurality of protruding portions 22 is 0.02 μm or less, and the flatness (local flatness) in a freely selected 20 mm square on a wafer W held through the tip surfaces 23 of the plurality of protruding portions 22 is 0.1 μm or less.

Furthermore, as described above, α-SiC is partly present around β-SiC in a mixed manner in the inner portion that has been subjected to grinding or polishing near the top surface 11 of the SiC member 10, and the residual stress is relaxed. Therefore, the deterioration of dimensional accuracy due to long-term use can be suppressed.

Accordingly, the substrate-holding member 20 which has high dimensional accuracy and whose dimensional accuracy can be maintained for a long time can be provided. The substrate-holding member 20 includes a substrate having a main surface 21 and a plurality of protruding portions 22 which protrude from the main surface 21 of the substrate with the same height and whose tip surfaces are flush with each other. By using the substrate-holding member 20, the substrate W can be held with good flatness for a long time.

### EXAMPLES

Hereafter, Examples and Comparative Examples of the present invention will be specifically mentioned to describe the present invention in detail.

### Example 1

First, a CVD step (STEP 1) of forming a CVD-SiC member was performed. Specifically, a CVD-SiC member was produced by a thermal CVD method in which a silicon carbide body was formed on a high-purity isotropic graphite material through thermal deposition. The raw material gas was a mixture gas of trichloromethylsilane (CH₃SiCl₃: MTS) and hydrogen gas. After the deposition, a CVD-SiC member was obtained by removing the graphite material.

The obtained CVD-SiC member was ground to form a disc-shaped CVD-SiC member having a diameter of 100 mm and a thickness of 5.0 mm. The CVD-SiC member was subjected to X-ray diffraction measurement using an X-ray diffractometer MultiFlex manufactured by Rigaku Corporation. The X-ray diffraction measurement was performed on a mirror-polished surface of the SiC member 10 using a Cu-Kα source (wavelength 1.54060 Å) under the following conditions: acceleration voltage 40 kV, 40 mA, scan step 0.02°, scan axis 2θ, and scan range 10° to 90°.

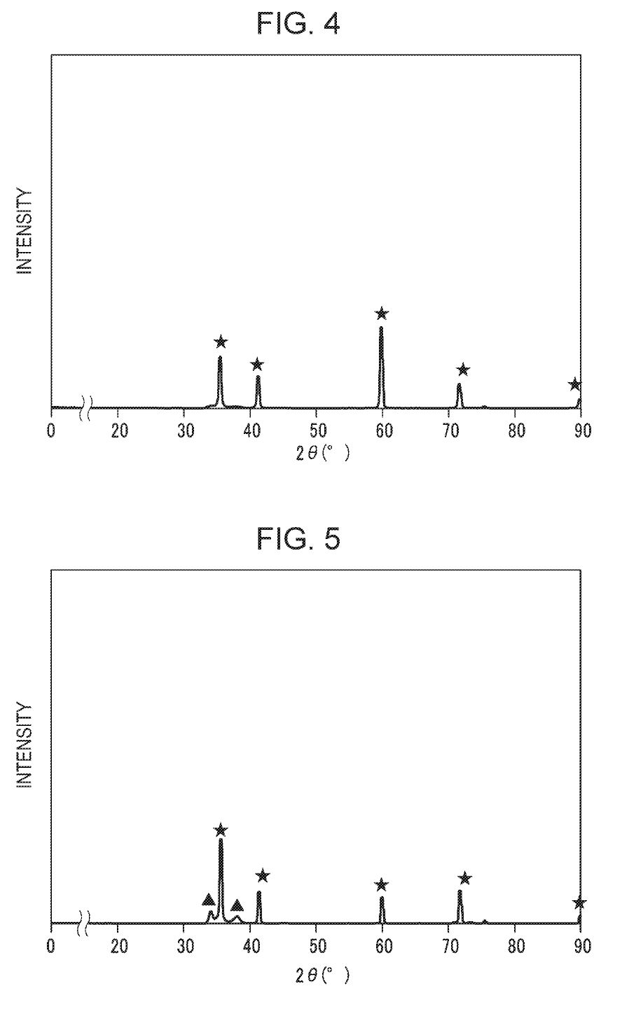

FIG. 4 illustrates the result of the X-ray diffraction measurement. In FIG. 4 to FIG. 6, triangles indicate the peak positions of 6H α-SiC and stars indicate the peak positions of 3C β-SiC.

It was found from FIG. 4 that the CVD-SiC member was formed of 3C β-SiC and did not contain α-SiC.

Subsequently, the heat treatment step (STEP 2) was performed. Specifically, the CVD-SiC member was inserted into a furnace and fired in an Ar atmosphere for two hours after the temperature reached 2070° C. to obtain a SiC member 10.

The obtained SiC member 10 was subjected to X-ray diffraction measurement as in the case of the CVD-SiC member. FIG. 5 illustrates the result of the X-ray diffraction measurement. It was found from FIG. 5 that the obtained SiC member 10 contained 6H α-SiC in addition to the 3C β-SiC. The ratio of the intensity of the maximum peak derived from 6H α-SiC at a diffraction angle 2θ of 34°±0.5° to the intensity of the maximum peak among diffraction peaks derived from 3C β-SiC was 3% or more and 30% or less.

### Example 2

A SiC member 10 was obtained in the same manner as in Example 1, except that the heat treatment temperature in the STEP 2 was changed to 2020° C. The obtained SiC member 10 was subjected to X-ray diffraction measurement as in Example 1. It was found that the obtained SiC member 10 contained 6H α-SiC in addition to the 3C β-SiC as in Example 1. The ratio of the intensity of the maximum peak derived from 6H α-SiC at a diffraction angle 2θ of 34°±0.5° to the intensity of the maximum peak among diffraction peaks derived from 3C β-SiC was 3% or more and 30% or less.

### Comparative Example 1

A SiC member 10 was obtained in the same manner as in Example 1, except that the heat treatment temperature in the STEP 2 was changed to 1950° C. The obtained SiC member 10 was subjected to X-ray diffraction measurement as in Example 1. It was found that the obtained SiC member 10 contained 6H α-SiC in addition to the 3C β-SiC as in Example 1. However, the ratio of the intensity of the maximum peak derived from 6H α-SiC at a diffraction angle 2θ of 340±0.50 to the intensity of the maximum peak among diffraction peaks derived from 3C β-SiC was as small as less than 3%, which showed that the amount of 6H α-SiC generated was small.

### Example 3

A CVD-SiC member was produced in the same manner as in Example 1. Herein, the obtained CVD-SiC member was ground to form a disc-shaped CVD-SiC member having a diameter of 302 mm and a thickness of 6.0 mm.

Then, the CVD-SiC member was heat-treated in the same manner as in Example 1 to obtain a SiC member 10.

The obtained SiC member 10 was ground and polished to form a disc-shaped SiC member 10 having a diameter of 300 mm and a thickness of 5.0 mm.

In the protruding portion forming step (STEP 3), protruding portions 22 having a diameter of 0.5 mm and a height of 200 μm were entirely formed on one surface (top surface 11) of the SiC member 10 at positions corresponding to vertexes of 6 mm squares and serving as the centers of the protruding portions 22. Furthermore, a ring-shaped protruding portion (ring-shaped rib) having a width of 0.2 mm and a height of 200 μm was formed on the outer periphery of the disc. In addition, a through hole for discharging air was formed at the center of the SiC member 10.

In the planarizing step (STEP 4), the resulting product was polished using a diamond loose abrasive. Thus, a substrate-holding member 20 was obtained.

Furthermore, a silicon wafer W having a diameter of 300 mm and a thickness of 0.7 mm was provided. The wafer W was placed on the upper surfaces of the plurality of protruding portions 22 and the ring-shaped protruding portion of the substrate-holding member 20. The flatness (local flatness) of a freely selected 20 mm square on the wafer W was measured with a laser interferometer manufactured by Zygo Corporation. A good flatness of 0.05 μm was achieved.

The surface roughness Ra of the protruding portions 22 was determined using a two-dimensional analysis function of the laser interferometer. A good surface roughness of 0.01 μm was achieved.

After three months, the flatness was measured again. The flatness was maintained and no deterioration was found.

### Comparative Example 2

A SiC member 10 that was not subjected to the heat treatment step (STEP 2) was ground and polished to form a disc-shaped SiC member 10 having a diameter of 300 mm and a thickness of 5.0 mm. A plurality of protruding portions 22, a ring-shaped protruding portion, and a through hole were formed on the SiC member 10 in the same manner as in Example 3. Furthermore, the planarizing step (STEP 4) was performed in the same manner as in Example 3. Thus, a substrate-holding member 20 was obtained.

Furthermore, the same wafer W as that in Example 3 was provided. The wafer W was placed on the upper surfaces of the plurality of protruding portions 22 and the ring-shaped protruding portion of the substrate-holding member 20. The flatness was measured in the same manner as in Example 3. A good flatness of 0.05 μm was achieved. The surface roughness Ra was also measured in the same manner as in Example 3. A good surface roughness of 0.008 μm was achieved.

After three months, the flatness was measured again. The flatness was deteriorated to 0.1 μm and the deterioration over time was confirmed.

### Comparative Example 3

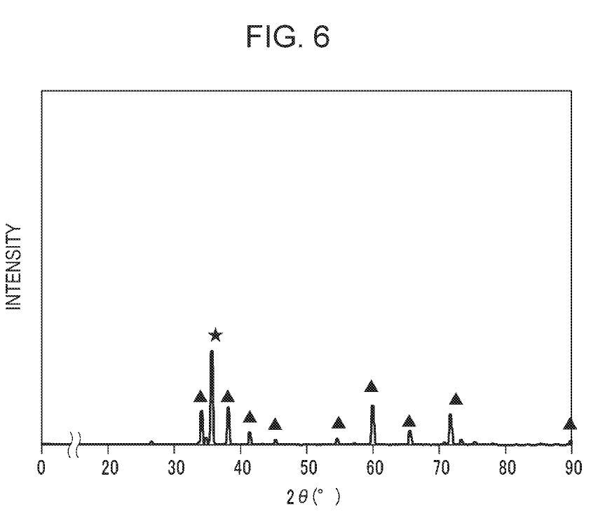

A SiC member 10 formed of α-SiC that is a commercially available sintered body was ground and polished to form a disc-shaped SiC member 10 having a diameter of 300 mm and a thickness of 5.0 mm. The obtained SiC member 10 was subjected to X-ray diffraction measurement in the same manner as in Example 1. FIG. 6 illustrates the result of the X-ray diffraction measurement. It was found from FIG. 6 that the obtained SiC member 10 was formed of 6H α-SiC.

Furthermore, a plurality of protruding portions 22, a ring-shaped protruding portion, and a through hole were formed on the SiC member 10 in the same manner as in Example 3, and the planarizing step (STEP 4) was performed in the same manner as in Example 3. Thus, a substrate-holding member 20 was obtained.

Furthermore, the same wafer W as that in Example 3 was provided. The wafer W was placed on the upper surfaces of the plurality of protruding portions and the ring-shaped protruding portion of the SiC member 10. The flatness was measured in the same manner as in Example 3. The flatness was as poor as 0.2 μm. The surface roughness Ra was measured in the same manner as in Example 3. The surface roughness was as poor as 0.04 μm.

What is claimed is:

1. A method for producing a SiC member, comprising:
forming the SiC member of β-SiC by chemical vapor deposition (CVD); and
heat-treating the SiC member in an inert atmosphere at a temperature of higher than 2000° C. and 2200° C. or lower to partly cause phase transition of the β-SiC into α-SiC.

2. A method for producing a substrate-holding member for holding a substrate, the method comprising:
producing the SiC member according to the method of claim 1;
forming a main surface positioned lower than a top surface of the SiC member by partly removing the top surface and forming a plurality of protruding portions that protrude from the main surface; and
planarizing tip surfaces of the plurality of protruding portions so that the tip surfaces protrude from the main surface with the same height so as to be flush with each other.

3. A SiC member comprising:
β-SiC and α-SiC,
wherein a ratio of an intensity of a maximum peak derived from the α-SiC at a diffraction angle 2θ of 34°±0.5° to an intensity of a maximum peak among diffraction peaks derived from the β-SiC in an X-ray diffraction spectrum is 3 or more and 30 or less.

4. A substrate-holding member comprising:
the SiC member according to claim 3,
wherein the SiC member includes a substrate having a main surface and a plurality of protruding portions which protrude from the main surface with the same height and whose tip surfaces are flush with each other.
